(19) United States
(12) Patent Application Publication
(10) Pub. No.: US 2014/0131208 A1
(43) Pub. Date: May 15, 2014

(54) METALLIC SHELL AND METHOD FOR ETCHING PATTERN

(71) Applicants: HON HAI PRECISION INDUSTRY CO., LTD., New Taipei (TW); HONG FU JIN PRECISION INDUSTRY (ShenZhen) CO., LTD, ShenZhen (CN)

(72) Inventors: CHIH-WEI CHIEN, New Taipei (TW); CHANG-WEN CHI, New Taipei (TW); WU YI, Shenzhen (CN); PO-AN CHEN, New Taipei (TW)

(73) Assignees: HON HAI PRECISION INDUSTRY CO., LTD., New Taipei (TW); HONG FU JIN PRECISION INDUSTRY (ShenZhen) CO., LTD, ShenZhen (CN)

(21) Appl. No.: 13/948,201

(22) Filed: Jul. 23, 2013

(30) Foreign Application Priority Data
Nov. 13, 2012 (CN) 2012104524609

(51) Int. Cl. C25D 11/02; H05K 5/04

(52) U.S. Cl. CPC C25D 11/022; H05K 5/04
USPC 205/50; 205/171

(57) ABSTRACT

A metallic shell includes a metal layer having an outer surface. The outer surface defines at least one engraving portion. Each engraving portion includes a base portion and a sidewall connected between the outer surface and the base portion. The metallic shell further includes a protective layer with a first color. The protective layer coats the outer surface and the base portion. A second antioxidation coating with a second color different from the first color is coated on the sidewall of the at least one engraving portion. A method for etching a pattern on a metallic shell is also provided.

### BACKGROUND

1. Technical Field

The present disclosure relates to metallic shells and a method for etching a pattern on the metallic shells.

2. Description of Related Art

Electronic devices, such as notebook computers, include a shell for receiving electronic components of the electronic device. A pattern is formed on an outer surface of the shell for identifying a trademark or manufacturer of the electronic device. However, the color of the pattern is the same as the color of the outer surface, which makes the pattern indistinctive and sometimes hard to read.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of a metallic shell having a pattern in accordance with an embodiment.

FIGS. 2-5 are perspective views for showing the etching process of the pattern on the metallic shell in FIG. 1.

FIG. 6 is a perspective view of a metallic shell having a pattern in accordance with another embodiment.

FIG. 7 is a flowchart of a method for etching a pattern on a metallic shell in accordance with an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

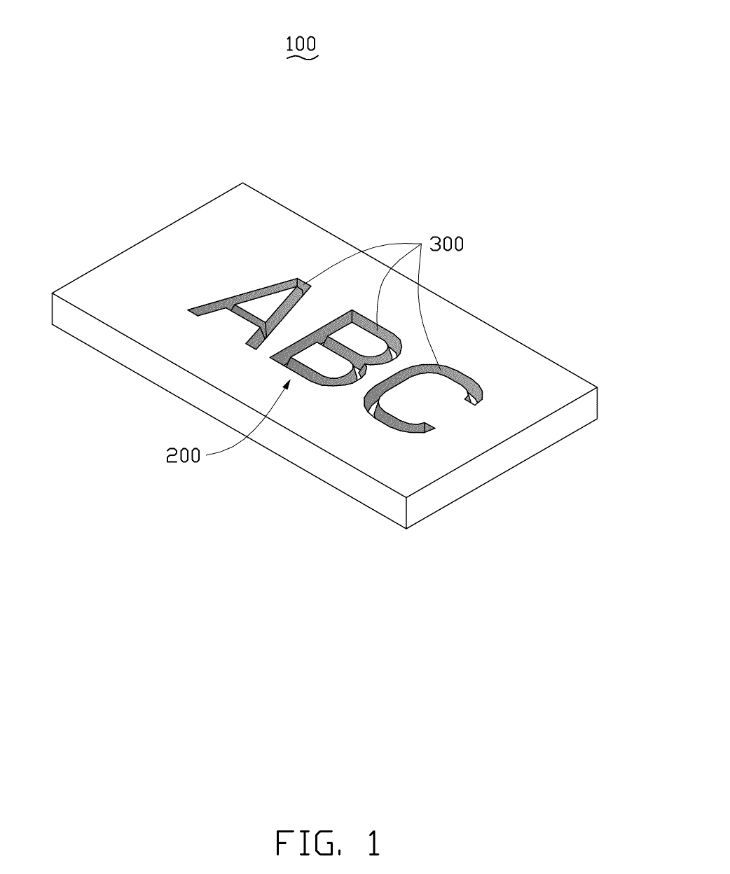

Referring to FIG. 1, a metallic shell 100 in accordance with an embodiment is shown. The metallic shell 100 functions as a housing of a product (not shown), such as a television, a notebook computer, or the like. The metallic shell 100 defines a pattern 200 for identifying a trademark or manufacturer of the product. The pattern 200 is integrally formed on the metallic shell 100 by a stamping process. The pattern 200 can be in the shape of letters, geometric figures, or the like.

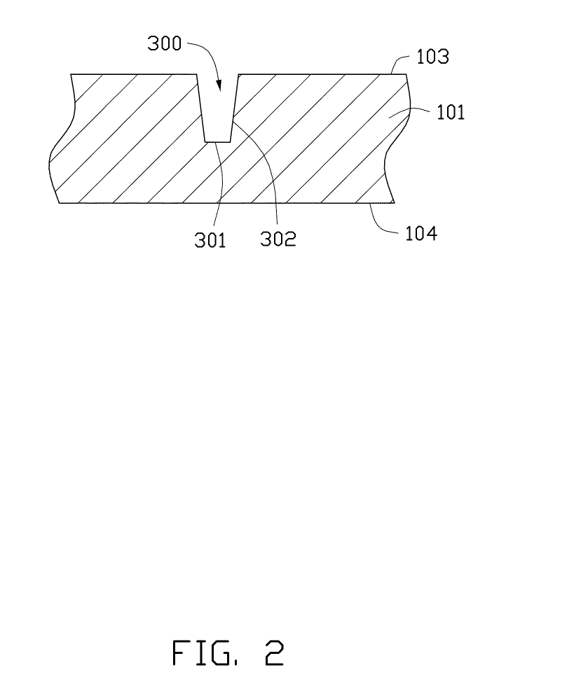

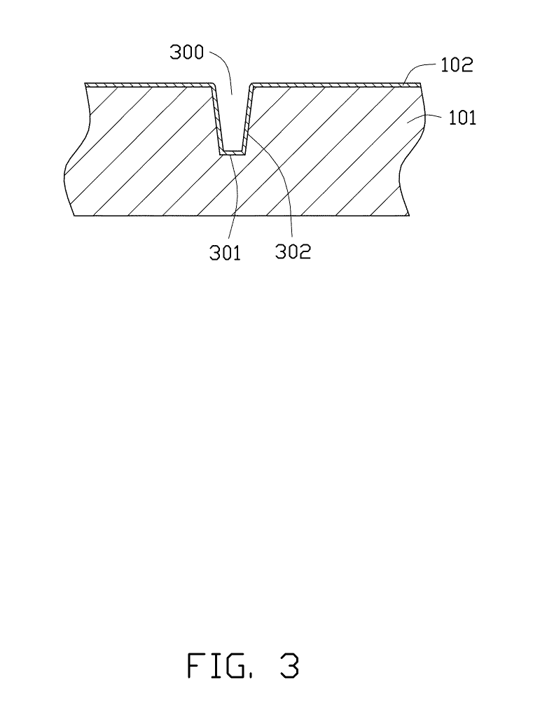

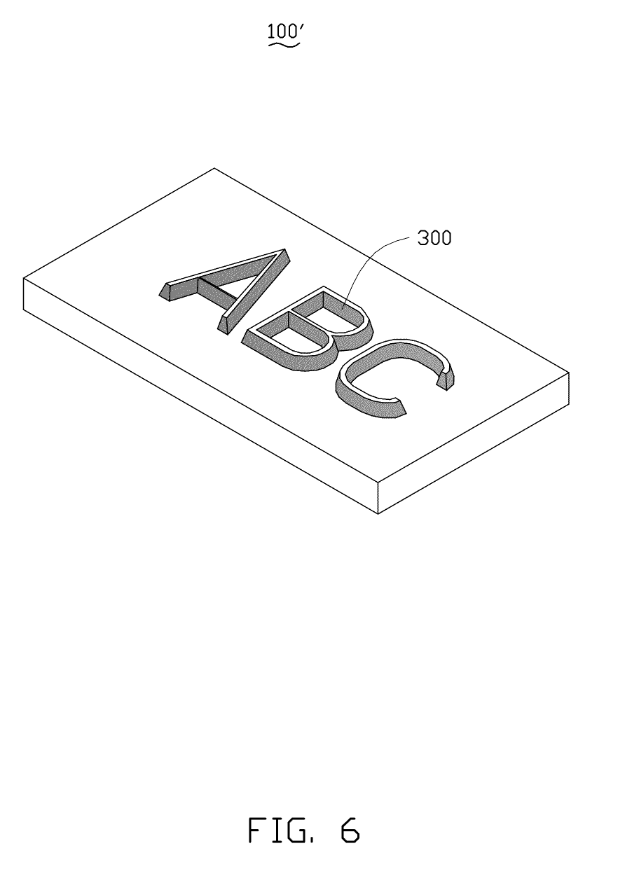

Referring to FIGS. 2 and 3, the metallic shell 100 includes a metal layer 101 and a protecting layer 102 coated on the metal layer 101. The metal layer 101 is made of metal material, such as aluminum or magnesium alloy, for example. The metal layer 101 includes an outer surface 103 and a bottom surface 104 opposite to the outer surface 103. The outer surface 103 defines a plurality of engraving portions 300. The engraving portions 300 cooperatively form the pattern 200. Each engraving portion 300 includes a base portion 301 parallel to the outer surface 103, and a sidewall 302 connected between the outer surface 103 and the base portion 301. In the embodiment, the engraving portions 300 recess from the outer surface 103 with the base portion 301 between the outer surface 103 and the bottom surface 104. In another embodiment, referring to FIG. 6, the engraving portions 300 may protrude out of the outer surface 103, such that the base portion 301 protrudes out of the outer surface 103.

The protecting layer 102 with a first color (such as silver) is formed by anodizing the metal layer 101 a first time. The protecting layer 102 evenly coats the outer surface 103, the bottom surface 104, the base portions 301, and the sidewalls 302. Because the outer surface 103, the base portions 301, and the sidewalls 302 are all coated by the protective layer 102, the color of the pattern 200 is substantially the same as the color of the metal layer 101. As a result, the color of the pattern 200 is not distinguished from the color of the metal layer 101.

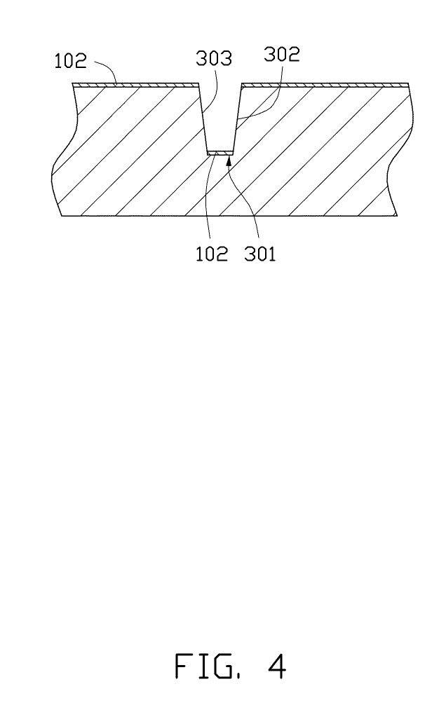

Referring to FIG. 4, to distinguish the pattern 200 from the metal layer 101, a portion of the protecting layer 102 coated on the sidewall 302 is removed by a cutting tool (such as a diamond milling cutter) to form a bare metal surface 303. Because the bare metal surface 303 has a metallic luster, the bare metal surface 303 is distinguished from the color of the protective cover 102. Therefore, the pattern 200 is distinct.

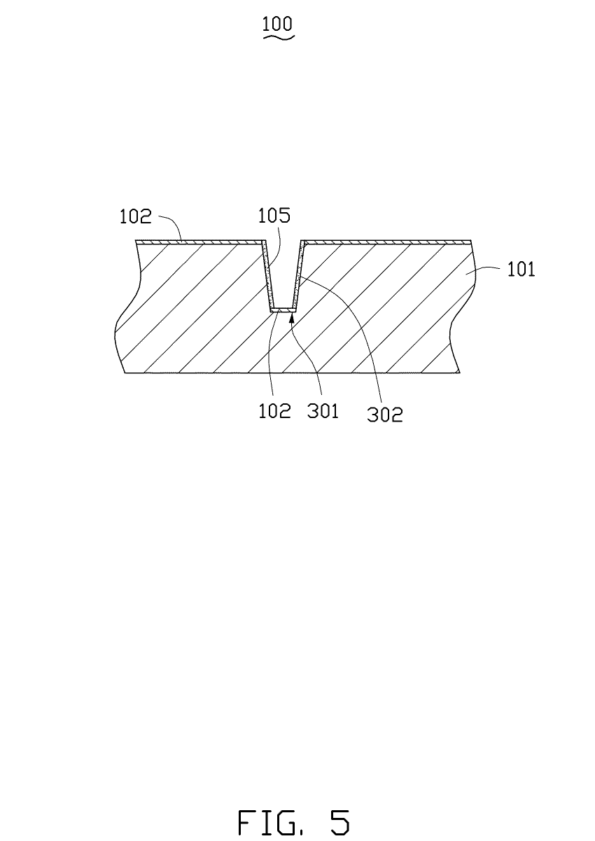

Referring also to FIG. 5, because the bare metal surface 303 is easily eroded when exposed to air, the bare metal surface 303 easily loses its metallic luster. To solve this problem, the metal layer 101 is anodized a second time to form an antioxidation coating 105 on the bare metal surface 303 to prevent the bare metal surface 303 from eroding. The antioxidation coating 105 has a second color different from the first color of the protecting layer 102. As a result, the pattern 200 is distinguished because of the contrast in color between the antioxidation coating 105 and the protecting layer 102.

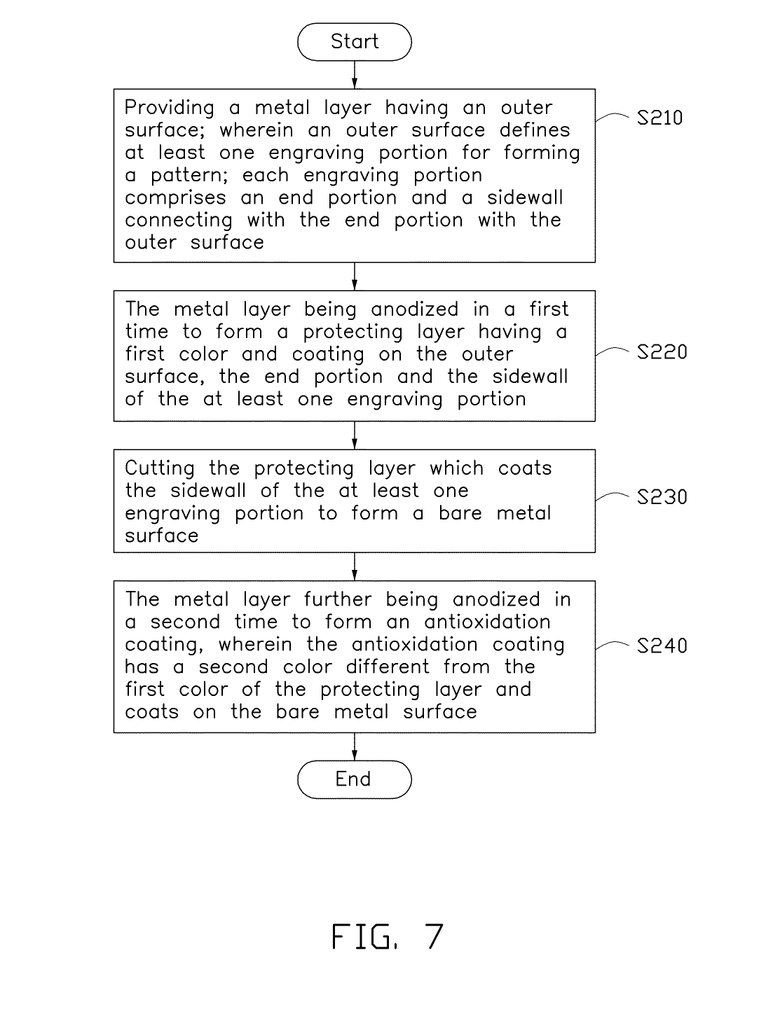

Referring to FIG. 7, a method for etching a pattern on a metallic shell 100 is provided. The method includes the following steps:

In step S210, a metal layer 101 is provided, wherein an outer surface 103 of the metal layer 101 defines a plurality of engraving portions 300 for forming the pattern 200. Each engraving portion 300 includes a base portion 301 and a sidewall 302 connected between the base portion 301 and the outer surface 103.

In step S220, the metal layer 101 is anodized a first time to form a protecting layer 102 having a first color, the protecting layer 102 coats the outer surface 103, the base portions 301, and the sidewalls 302.

In step S230, a portion of the protecting layer 102 coating the sidewall 302 is removed by a cutting tool (such as diamond milling cutter) to form a bare metal surface 303.

In step S240, the metal layer 101 is anodized a second time to form an antioxidation coating 105 coating the bare metal surface 303, the antioxidation coating 105 having a second color different from the first color of the protecting layer 102. As a result, the pattern 200 is distinguished because of the contrast in color between the antioxidation coating 105 and the protecting layer 102.

Although information as to, and advantages of, the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A metallic shell, comprising:
a metal layer having an outer surface; the outer surface defining at least one engraving portion; each engraving portion comprising a base portion and a sidewall connecting the outer surface with the base portion; and
a protective layer with a first color coating the outer surface and the base portion of the at least one engraving portion;
wherein the sidewall of the at least one engraving portion is a bare metal surface having a metallic luster to distinguish from the color of the protective cover, whereby the at least one engraving portion is distinct.

2. The metallic shell of claim 1, wherein an antioxidation coating with a second color different from the first color coats on the bare metal surface.

3. The metallic shell of claim 1, wherein the metallic shell is used for a housing of a product, and the at least one engraving portion is used for identifying the trademark or manufacturer of the product.

4. A metallic shell, comprising:
a metal layer having an outer surface; the outer surface defining at least one engraving portion; each engraving portion comprising an base portion and a sidewall connecting the outer surface with the base portion;
a protective layer with a first color and coating the outer surface and the base portion; and
a second antioxidation coating with a second color different from the first color coating the sidewall of the at least one engraving portion.

5. The metallic shell of claim 4, wherein the protecting layer is formed by anodizing the metal layer a first time.

6. The metallic shell of claim 5, wherein the protecting layer coats the sidewall of the at least one engraving portion when the metal layer has being anodized a first time.

7. The metallic shell of claim 6, wherein the protecting layer which coats the sidewall of the at least one engraving portion is removed to form a bare metal surface, and the metal layer is further being anodized a second time to form the antioxidation coating on the bare metal surface.

8. The metallic shell of claim 4, wherein the metallic shell is used for a housing of a product, and the at least one engraving portion is used for identifying the trademark or manufacturer of the product.

9. A method for etching pattern on a metallic shell, the method comprising:
providing a metal layer having an outer surface; wherein an outer surface defines at least one engraving portion for forming a pattern; each engraving portion comprises a base portion and a sidewall connecting the base portion with the outer surface;
the metal layer being anodized a first time to form a protecting layer having a first color and coating on the outer surface, the base portion and the sidewall of the at least one engraving portion;
removing the protecting layer which coats the sidewall of the at least one engraving portion to form a bare metal surface; and
the metal layer further being anodized a second time to form an antioxidation coating, wherein the antioxidation coating has a second color different from the first color of the protecting layer and coats on the bare metal surface.

10. The method of claim 9, wherein the metallic shell is used for a housing of a product, and the at least one engraving portion forms the pattern for identifying the trademark or manufacturer of the product.
